(19) United States
(12) Patent Application Publication
(10) Pub. No.: US 2003/0181027 A1
(43) Pub. Date: Sep. 25, 2003

(54) Method of forming a polysilicon layer

(76) Inventors: Chao-Hu Liang, Hsin-Chu Hsien (TW); Chih-Hung Chen, Hsin-Chu City (TW); Yu-Shan Tai, Hsin-Chu City (TW); Po-Lun Cheng, Kao-Hsiung Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 10/063,128

(22) Filed: Mar. 25, 2002

(51) Int. Cl. H01L 21/20

(52) U.S. Cl. 438/584

(57) ABSTRACT

A surface of a semiconductor wafer has a first gate oxide area and a second gate oxide area. A first gate oxide layer and a photoresist layer are formed on the surface of the semiconductor wafer. A wet etching process is performed to remove the first gate oxide layer not in the first gate oxide area on the surface of the semiconductor wafer. The photoresist layer is then removed. After performing a wet cleaning process, a second gate oxide layer is formed on the surface of the semiconductor wafer. Finally, a two-step polysilicon deposition process is performed, the resultant polysilicon layer covering the first gate oxide area and the second gate oxide layer. The two-step polysilicon deposition process involves a first-step low temperature amorphous silicon (α-Si) deposition process, and a second-step high temperature polysilicon deposition process so as to avoid the formation of particles and defects when forming the polysilicon layer.

### BACKGROUND OF INVENTION

1. Field of the Invention

The present invention relates to a method for forming a polysilicon layer. In particular, the present invention discloses a two-step polysilicon layer formation method.

2. Description of the Prior Art

In the manufacturing of semiconductor devices, polysilicon is an essential material. It is made into materials that have different properties by utilizing different process conditions, which are then used for different semiconductor devices. Such devices include the gate of a transistor, the top and bottom electrodes of a capacitor, the resistor and gate for memory devices, etc. The flexibility of polysilicon enables it to fulfill the material specifications for the design of each device.

However, the polysilicon deposition process is very sensitive to the surface conditions of the wafer, especially when performing a dual gate process. It is necessary to fabricate gate oxide layers with differing degrees of thickness, and the dual gate process is most likely to generate particles and residue. The reason for this is that, before forming the second gate oxide layer, it is necessary to perform processes that tend to generate particles and residue, such as a photoresist coating step, a development step, a photoresist stripping step in the photolithography process, and an etching process for the silicon oxide gate layer.

Consequently, after the photoresist stripping process, a megasonic scrubbing process and a wet RCA cleaning process are normally performed. Thereafter, the deposition for the second gate oxide layer is performed. The purpose for performing these processes are not only to strip the photoresist, clean the wafer and neutralization, but also to remove any particles, organic substances and metal particles adhering to the wafer, as well as to remove micro-defects. By performing these processes, problems, such as a decrease of the breakdown voltage for the gate oxide layer, an increase of the junction leakage current, and changes of the oxidation rate, are avoided.

Please refer to FIG.1 to FIG.5. FIG.1 to FIG.5 are schematic diagrams of a method for making a dual gate on a semiconductor wafer 10 according to the prior art. As shown in FIG.1, the semiconductor wafer 10 comprises a substrate 12, a first gate oxide area 13 and a second gate oxide area 14, which are disposed on the surface of the substrate 12. A plurality of field oxide layers 16 are further disposed within both the first gate oxide area 13 and the second gate oxide area 14. The field oxide layers 16 are disposed on the surface of the substrate 12 and define active areas 15. The prior art method utilizes a dry oxidation process in order to form a first gate oxide layer 18 with a thickness of approximately 57 Å on the surface of the substrate 12. As shown in FIG.2, a photoresist layer 22 is formed on the surface of the substrate 12. A photolithography process is then performed in order to leave the active area 15 in the first gate oxide area 13 covered with the photoresist layer 22.

As shown in FIG.3, a wet etching process is performed that utilizes a buffer oxide etchant (BOE) as an etching solution to remove the those portions of the first gate oxide layer 18 that are not covered by the photoresist layer 22. The photoresist layer 22 is then removed. When removing the photoresist layer 22, a sulfuric acid-hydrogen peroxide mixture (SPM) solution is usually utilized. Further, before removing the photoresist layer 22, a SC-1 cleaning process and a spin dry process are usually performed. The objective for these two processes is to remove as many contaminants as possible, such as cracked oxide layers, residual etching solution and organic particles, so that the photoresist stripping process will be as effective as possible.

After the photoresist stripping process, a wet etching process is performed. Usually, a megasonic scrubbing process is performed first. By utilizing vibration of the megasonic scrubbing, contaminants adhering to the semiconductor wafer 10 are removed. Afterwards, a SC-1 cleaning process is performed. The SC-1 cleaning process utilizes an ammonium hydrogen peroxide mixture (APM) solution with a high PH value so as to remove organic contaminants and particles by way of an oxidation reaction at a temperature that ranges from 80 to 90° C. Thereafter, a SC-2 cleaning process is performed. A hydrochloric acid hydrogen peroxide mixture (HPM) solution with a low PH value is utilized to form soluble complex ions at a temperature ranging from 80 to 90° C. in order to remove metallic contaminants.

As shown in FIG.4, another dry oxidation process is performed to form a second gate oxide layer 24 with a thickness of approximately 33 Å on the surface of the semiconductor substrate 12. When forming the second gate oxide layer 24, some of the thickness of the first gate oxide layer 18 is consumed. Therefore, the thickness of the first gate oxide layer 18 is, in the end, greater than the thickness of the second gate oxide layer 24, but is less than the sum of the thickness of a double oxidation.

As shown in FIG.5, a low pressure chemical vapor deposition (LPCVD) method is used to perform a polysilicon deposition process, which forms a polysilicon layer (not shown) on the first gate oxide layer 13 and the second gate oxide layer 14. The LPCVD process can not only be performed in batch type equipment, but can also be performed in single wafer equipment (equipment which processes one wafer at a time). The process conditions for the former are: utilizing silane (SiH₄) as a reaction gas, a process temperature between 580° C. to 630° C., and a process pressure of approximately 0.2 torr. The process conditions for the latter are: utilizing silane (SiH₄) as a reaction gas, a process temperature of between 680° C. to 710° C., and a process pressure of between 40 to 80 torr. The latter has the advantage of a quick deposition rate, but only processes one wafer at a time. Afterwards, a photolithography and etching process is performed to form a first gate 26 and a second gate 28 in the first gate oxide area 13 and the second gate oxide area 14 on the semiconductor wafer 10.

One after another various cleaning processes are performed before the polysilicon deposition process in order to achieve the objective of removing various particulate contaminants. However, it has been discovered that the partial or overall particulate contamination occurs on the surface of the semiconductor wafer after the polysilicon deposition process, with even some needle-like particles present. This phenomenon results from process limitations of the scrubbing and cleaning processes. It is possible that trace particles, metal ions and organic substances still remain on the semiconductor wafer after cleaning. Under mass production theories in the semiconductor industry, a cleaning standard must be established for use as a process control of each production line, so that the amount of particulate contamination before performing a polysilicon deposition process fulfills the inspection standard. When forming the polysilicon layer, the higher the process temperature, the quicker the deposition rate, and crystallinity is more obvious. When the process temperature is too high, the reaction will tend towards homogeneous nucleation, which forms more grains. Therefore, during the polysilicon deposition process, the crystallinity direction is more easy to grow via existent particles, so a partial or overall particle contamination will occur on the surface of the polysilicon layer after deposition.

Please refer to FIG.6. FIG.6 is a cross-sectional diagram of forming a first gate and a second gate on the semiconductor wafer 10 according to the prior art. A protrusion 32 in FIG.6 is a particle. When the deposition thickness for the polysilicon layer 26 is 2 k Å, the height of the particle may be up to 5 μm. Please refer to FIG.7. FIG.7 shows particle distribution on the semiconductor wafer 10 after forming the first gate and the second gate according to the prior art.

It is important to develop a new polysilicon process which will not make the cleaning process more complex, nor increase the cost of the cleaning process, and which avoids partial or overall particle contamination and needlelike contamination during polysilicon deposition.

### SUMMARY OF INVENTION

It is therefore a primary objective of the present invention to provide a method for making a polysilicon film to solve the problems of particle contamination and needle-like contamination.

In the preferred embodiment of the present invention, the present invention provides for forming a polysilicon film on a semiconductor wafer. The surface of the semiconductor wafer comprises a first gate oxide area and a second gate oxide area. A first gate oxide layer and a photoresist layer are formed on the surface of the semiconductor wafer. A wet etching process is performed to remove the first gate oxide layer not in the first gate oxide area on the surface of the semiconductor wafer. The photoresist layer is then removed. After performing a wet cleaning process, a second gate oxide layer is formed on the surface of the semiconductor wafer. Finally, a two-step polysilicon deposition process is performed, the resultant polysilicon layer covering the first gate oxide area and the second gate oxide layer. The two-step polysilicon deposition process comprises a first-step low temperature amorphous silicon (α-Si) deposition process, and a second-step high temperature polysilicon deposition process so as to avoid the formation of particles and defects when forming the polysilicon layer.

It is an advantage of the present invention that the two-step polysilicon deposition process forms the polysilicon layer, which is composed of an amorphous silicon layer and a polysilicon layer. Therefore, the growth of nucleation is inhibited by utilizing a non-obvious crystallinity characteristic when forming amorphous silicon, and further avoiding the growth of grains due to small and large particles adhering to the surface of the semiconductor wafer during crystallization. The present invention better prevents the occurrence of particles and defects of various shapes, without increasing the cost of the cleaning step in a previous process.

### BRIEF DESCRIPTION OF DRAWINGS

FIG.1 to FIG.5 are schematic diagrams of the method for making a dual gate on a semiconductor wafer according to the prior art.

FIG.6 is a cross-sectional diagram of forming a first gate and a second gate on a semiconductor wafer according to the prior art.

FIG.7 shows a particle distribution on a semiconductor wafer after forming a first gate and a second gate according to the prior art.

FIG.8 to FIG.13 are schematic diagrams of the method for making a dual gate on a semiconductor wafer according to the present invention.

FIG.14 is a particle distribution on a semiconductor wafer after forming a first gate and a second gate according to the present invention.

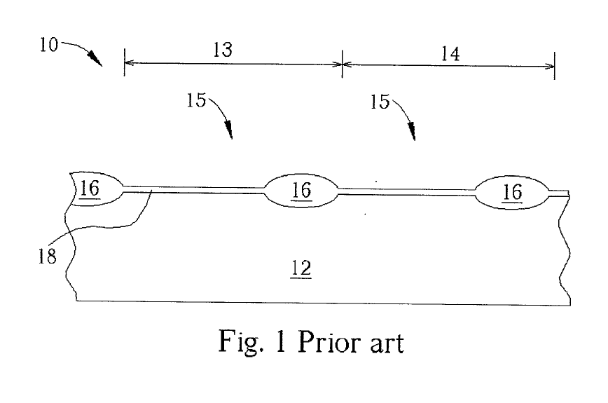

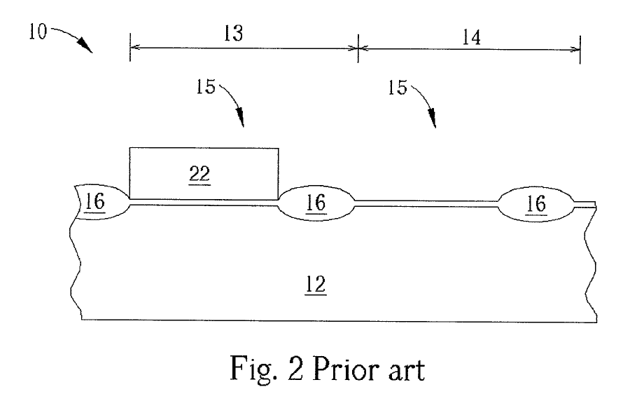

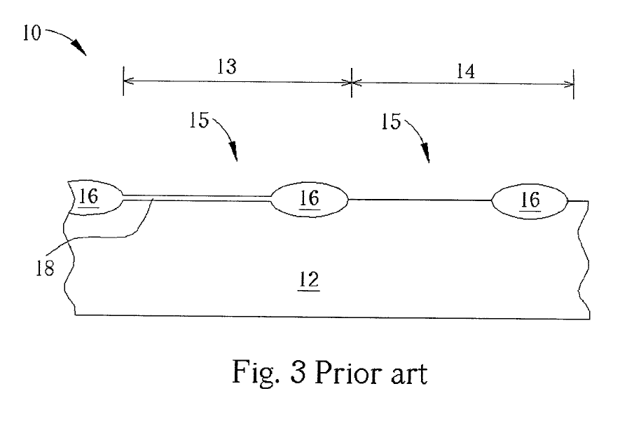

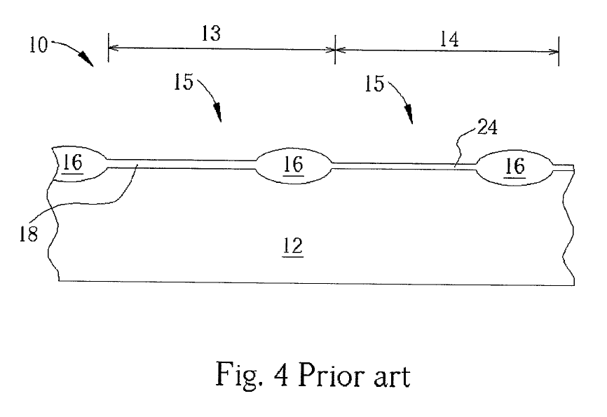

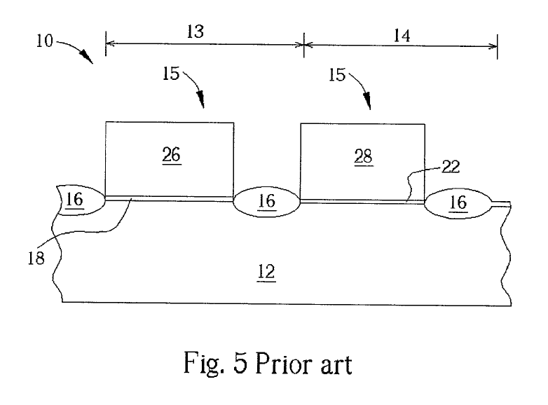

### DETAILED DESCRIPTION

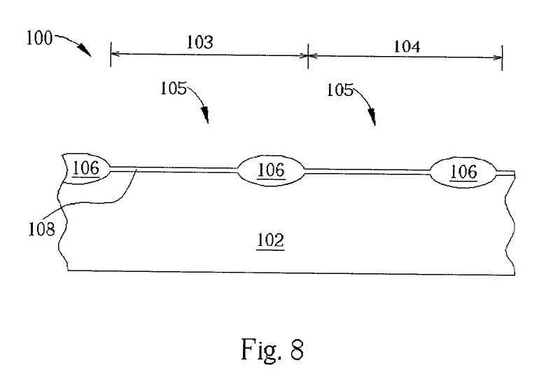

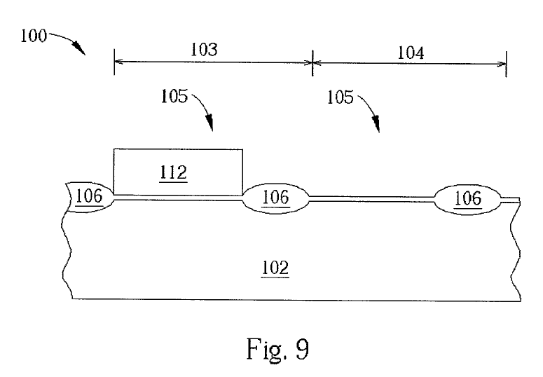

Please refer to FIG.8 to FIG.13. FIG.8 to FIG.13 are schematic diagrams of the method for making a dual gate on a semiconductor wafer 100 according to the present invention. As shown in FIG.8, the semiconductor wafer 100 comprises a substrate 102, with a first gate oxide area 103 and a second gate oxide area 104 on the surface of the substrate 102. A plurality of field oxide layers 106 are disposed in both the first gate oxide area 103 and the second gate oxide area 104. The field oxide layers 106 cover portions of the surface of the substrate 102, and define active areas 105. The present invention method utilizes a dry oxidation process in order to form a first gate oxide layer 108 with a thickness of approximately 57 Å on the surface of the substrate 102. As shown in FIG.9, a photoresist layer 112 is then formed on the surface of the substrate 102. A photolithography process is performed, which leaves the active area 105 in the first gate oxide area 103 covered with the photoresist layer 112.

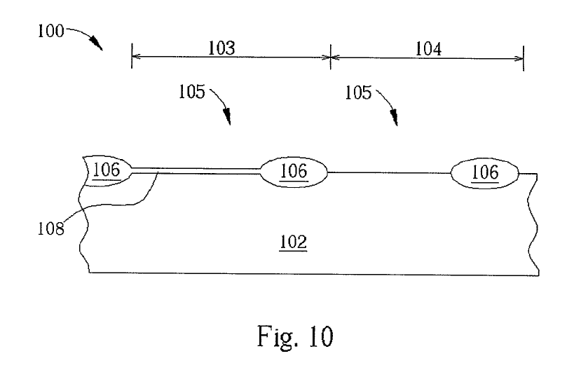

As shown in FIG.10, a wet etching process is performed, which utilizes a buffer oxide etchant (BOE) as an etching solution to remove those portions of the first gate oxide layer 108 that are not covered by the photoresist layer 112. A SC-1 cleaning process and spin drying are then performed to remove particulate contaminants, such as cracked oxide layers, residual etching solution, and organic substances. Finally, the photoresist layer 112 is removed with a sulfuric acid-hydrogen peroxide mixture (SPM).

After removing the photoresist layer 112 , a wet etching process is performed. Usually, a megasonic scrubbing process is first performed. By utilizing vibration of the megasonic scrubbing process, contaminants adhering to the semiconductor wafer 100 are removed. An ammonium hydrogen peroxide mixture (APM) solution, having a high PH value, is then used to remove organic contaminants and particles by way of an oxidation reaction at a temperature ranging from 80 to 90° C. Finally, a SC-2 cleaning process is performed. A hydrochloric acid hydrogen peroxide mixture(HPM) solution, having a low PH value and at a temperature ranging from 80 to 90° C., forms soluble complex ions so as to remove metallic contaminants.

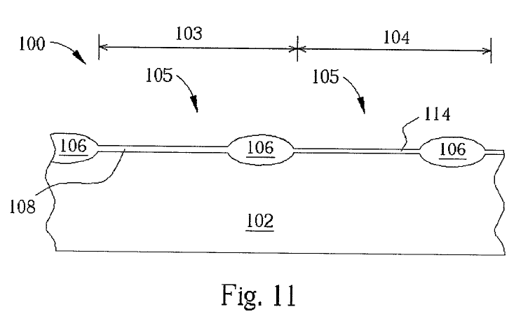

As shown in FIG.11, another dry oxidation process is used to form a second gate oxide layer 114 with a thickness of approximately 33 Å on the surface of the semiconductor substrate 102. When forming the second gate oxide layer 114, some of the thickness of the first gate oxide layer 108 will be consumed. Therefore,a final thickness of the first gate oxide layer 108 is greater than the thickness of the second gate oxide layer 114, but is less than the sum of the thickness for a double oxidation.

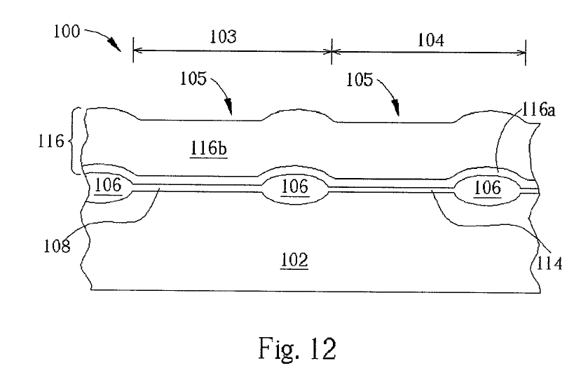

As shown in FIG.12, a two-step low pressure chemical vapor deposition (LPCVD) process is then used to form a polysilicon layer 116 on the first gate oxide layer 103 and the second gate oxide layer 104. The two-step LPCVD process is performed in single wafer equipment, which processes one wafer at a time. The process conditions for the first stepare: utilizing silane (SiH₄) as a reaction gas, a process temperature that is between 550° C. to 650° C., and a process pressure that is between 40 and 80 torr. A first amorphous silicon layer 116a is deposited with a thickness of approximately 100 Å. Then, a second step polysilicon deposition process is performed. The process conditions for the second polysilicon deposition process are: utilizing silane (SiH₄) as a reaction gas, a process temperature that is between 680° C. to 710° C., and a process pressure that is between 40 and 80 torr. A second polysilicon layer 116b is deposited with a thickness of approximately 2000˜2500 Å. The first amorphous layer 116a and the second polysilicon layer 116b together form the first polysilicon layer 116.

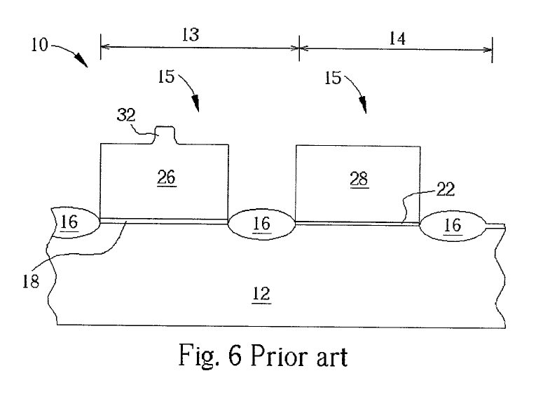

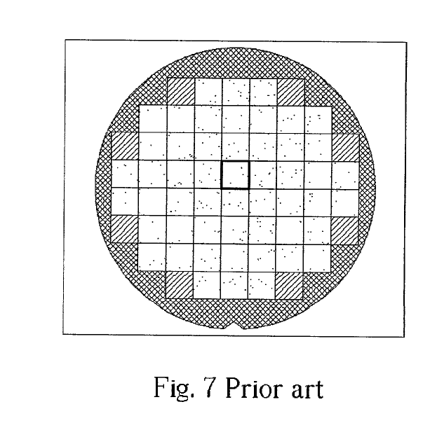

The advantage of the two-step polysilicon deposition process according to the present invention is that depositing with a low temperature first, in which the crystallinity is not marked, tends to form an amorphous silicon (α-Si) structure. Nucleation is thus effectively inhibited to further avoid grains growing by way of small and large particles on the surface of the semiconductor wafer during crystallization, which would otherwise result in the occurrence of protrusions and defects as shown in FIG.6. The composite polysilicon layer of the present invention can be formed in a batch type LPCVD equipment with adequate tuning of parameters.

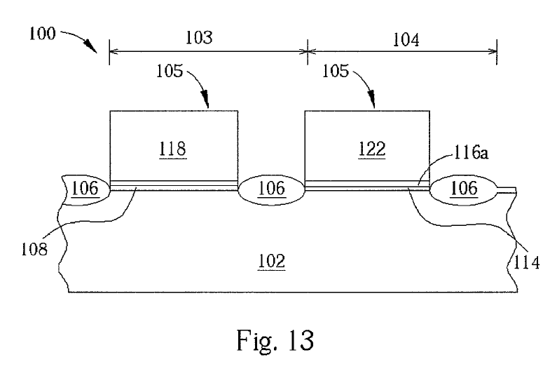

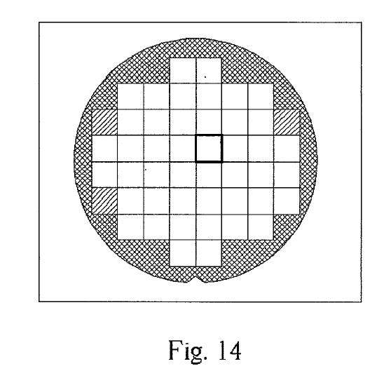

Finally, as shown in FIG.13, a photolithography and etching process is performed so as to form a first gate 118 and a second gate 122 in the first gate oxide area 103 and the second gate oxide area 104, respectively, on the semiconductor wafer 10.Please refer to FIG.14. FIG.14 shows particle distribution on the semiconductor wafer 100 after forming the first gate 118 and the second gate 122 according to the present invention.

In the present invention, the method for forming the polysilicon layer utilizes a two-step polysilicon deposition process. This involves first forming an amorphous silicon layer at a low temperature, and then forming a polysilicon layer at a high temperature. Since the crystallinity during the amorphous silicon formation is not apparent, the growth of nucleation can be inhibited. Consequently, grains growing via small and large particles adhering on the surface of the semiconductor wafer during crystallization, and which thus generate various unexpected needle-like particles, can be avoided. Without the need for changes or additions to the previous cleaning processes, such as the cleaning steps after wet etching and photoresist stripping, and the cleaning step before the second gate oxide layer deposition, the present invention shows marked improvement in preventing the occurrence of particles and defects of various shapes and sizes. No increase in the cost of the cleaning processes is incurred by the present invention.

In contrast to the prior art method, the present method for forming a polysilicon layer utilizes a two-step polysilicon deposition process. This involves first forming an amorphous silicon layer at a low temperature, and then forming a polysilicon layer at a high temperature. As crystallinity during the amorphous silicon formation is not readily present, the growth of nucleation is inhibited. Grains that tend to grow by way of small and large particles adhering on the surface of the semiconductor wafer during crystallization are thus avoided. Under the premise of not increasing the cost of the cleaning steps in the previous process, the two-step polysilicon deposition process according to the present invention displays clear improvement in preventing the occurrence of particles and defects.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method for making a polysilicon film on a semiconductor wafer, the surface of the semiconductor wafer comprising a plurality of particles, the method comprising:
performing a two-step polysilicon deposition process, the two-step polysilicon deposition process comprising:
a first step amorphous silicon (α-Si) deposition process utilizing a low temperature; and
a second step polysilicon deposition process utilizing a high temperature; wherein the first step amorphous silicon (α-Si) deposition process is used to avoid nucleation of the polysilicon film growth, which utilizes the particles on the surface of the semiconductor wafer, so as to inhibit occurrences of needle-like particles and defects on the surface of the polysilicon film.

2. The method of claim 1 wherein before performing the two-step polysilicon deposition process, at least one photolithography process, one wet etching process, one photoresist stripping process, one wet cleaning process and one thermal oxidation process are performed on the surface of the semiconductor wafer.

3. The method of claim 2 wherein the wet etching process comprises a buffer oxide etchant (BOE) etching process and a SC-1 cleaning process.

4. The method of claim 2 wherein the wet etching process comprises a megasonic scrubbing process, a SC-1 cleaning process, and a SC-2 cleaning process.

5. The method of claim 1 wherein the particles comprise micro particles, organic substances, metallic particles adhered to the semiconductor wafer, and micro-defects.

6. The method of claim 1 wherein a temperature of the first step amorphous silicon deposition process ranges from 550 to 650° C., and a thickness for the amorphous silicon layer is approximately 100 Å.

7. The method of claim 1 wherein a temperature of the second step polysilicon deposition process ranges from 680 to 710° C.

8. The method of claim 1 wherein the two-step polysilicon deposition process is performed in single wafer type low pressure chemical vapor deposition (LPCVD) equipment.

9. A method for forming a polysilicon film on a semiconductor wafer, a surface of the semiconductor wafer comprising a first gate oxide area and a second gate oxide area, the method comprising:
forming a first gate oxide layer (GOX layer) on the surface of the semiconductor wafer;
performing a photolithography process and an etching process to remove the first gate oxide layer on the surface of the second gate oxide area;
performing a cleaning process; and
performing a two-step polysilicon deposition process to form a polysilicon layer, the polysilicon layer covering the first gate oxide area and the second gate oxide area;
wherein the two-step polysilicon deposition process comprises a first step low temperature amorphous silicon (α-Si) deposition process to avoid formation of particles and defects during the formation of the polysilicon layer, and a second step high temperature polysilicon deposition process.

10. The method of claim 9 wherein the etching process is a wet etching process.

11. The method of claim 10 wherein the wet etching process utilizes a buffer oxide etchant (BOE) as an etching solution.

12. The method of claim 9 wherein the cleaning process is a wet cleaning process.

13. The method of claim 12 wherein the wet cleaning process comprises:
performing a megasonic scrubbing process;
performing a SC-1 cleaning process; and
performing a SC-2 cleaning process.

14. The method of claim 9 wherein a temperature of the first step low temperature amorphous silicon deposition process ranges from 550 to 650° C.

15. The method of claim 9 wherein a temperature of the second step high temperature polysilicon deposition process ranges from 680 to 710° C.

16. The method of claim 9 wherein the two-step polysilicon deposition process is performed in single wafer type low pressure chemical vapor deposition (LPCVD) equipment.

17. The method of claim 9 wherein the defects comprise needle-like defects.
